(19) United States
(12) Patent Application Publication
(10) Pub. No.: US 2026/0310842 A1
(43) Pub. Date: Oct. 8, 2026

(54) METHOD AND SYSTEMS FOR DESIGNING DRIVE SYSTEMS

(71) Applicant: Siemens Aktiengesellschaft, München (DE)

(72) Inventors: KARL-JOSEF AMTHOR, Erlangen (DE); JOCHEN BRETSCHNEIDER, Erlangen (DE); ERICH GÜNTHER, Erlangen (DE); CARSTEN HAMM, Erlangen (DE); CHRISTIAN NEUGEBAUER, Erlangen (DE)

(73) Assignee: Siemens Aktiengesellschaft, München (DE)

(21) Appl. No.: 19/481,419

(22) PCT Filed: Mar. 28, 2024
(86) PCT No.: PCT/EP2024/058479

§ 371 Date: Nov. 4, 2025

(30) Foreign Application Priority Data
May 5, 2023 (EP) 23171881.8

(51) Int. Cl. G06F 30/17

(52) U.S. Cl. CPC G06F 30/17

(57) ABSTRACT

A computer-aided method is used for designing a drive system which directly Influences a control section and forms an overall system. A drive twin and route model are provided. The drive twin is linked to the route model to form a runnable digital twin of the entire system, a complete twin. When the drive twin is linked, a start parameter set of the drive twin is determined. The entire twin is executed to simulate the overall system and obtain simulation results. The drive system of the overall system is designed according to the starting parameter set. The simulation results are compared with the behavior of the overall system. If the behavior of the overall system deviates from the simulation results, the drive twin is optimized. An optimized parameter set of the drive twin is obtained. The drive system of the overall system is designed with the optimized parameter set.

Independent of the grammatical term usage, individuals with male, female or other gender identities are included within the term.

The present disclosure relates to a computer-assisted method and a system for designing at least one drive system, which directly influences a controlled system—and thus controls a process, in particular in a closed-loop manner (in this case closed-loop controlled system), wherein the drive system and the controlled system together form an overall system.

Moreover, the present disclosure relates to a computing facility comprising an engineering platform, which is configured to carry out or orchestrate the aforementioned method.

The present disclosure also relates to a computer program, which comprises commands which, when these are executed by the aforementioned computing facility, prompt it to carry out the aforementioned method.

In addition, the present disclosure relates to a machine-readable medium with such a computer program.

The topic of designing a drive system or its subsystem (object, such as converter, motor, etc.) can be highly complex. The aim is mostly the optimization according to chosen criteria (costs, performance, in particular the set duration of a closed-loop control variable, energy consumption, space requirements etc.). This includes both choosing the correct components as well as choosing the correct combination thereof.

Before an installation is automated or before an automation installation can be constructed, project planning must take place. In this context, appropriate installation components must be selected for a task that is to be achieved by the automation installation, i.e. an installation that contains automation components. This also includes designing the drive systems for the installation components.

In this context, the designing depends upon a specific usage scenario, for example such as supporting commissioning, supporting diagnostics, supporting training measures, etc.

This optimization typically takes place on the basis of static data, i.e. catalog data, label data, etc., which in particular is not updated and does not depend upon operating behavior of the drive system and/or the dynamics in the usage scenario. What is particularly disadvantageous here is that optimization on the basis of (dynamic) characteristics of the system is not possible. It is known to design using only one optimization criterion (frame size or price), for example. In this context, it is not possible to automate the design, or it is not possible to do so fully, as the validation of the project planning first takes place with the real device or this is left to the imagination and the experience of the user.

For designing, it is also possible to use calculation results that are achieved with the aid of digital twins of the drive systems, which can be incorporated into simulation tools.

In principle, a digital twin of a drive system is a virtual representation of the real drive system and preferably is capable of being configured in real time, if it is uploaded by data obtained from sensors and other data sources in real time, for example. This digital twin can be based on a large number of data sources, such as operating data, construction drawings and models, maintenance histories and other information that has been collected over the course of the service life of the drive system.

The digital twin can enable a large number of functions, such as monitoring, simulation and prediction of output and status of the drive system. It can also be used as a digital model for optimizing maintenance processes and improving the output. Moreover, it can also contribute towards reducing failure times and maintenance costs, by identifying potential problems at an early stage and recommending appropriate measures. It can be used in order to also improve the efficiency of the drive system, by ascertaining and proposing optimum operating conditions and monitoring the output over time.

A digital twin of the drive system can also offer a powerful option for optimizing the output and efficiency of the drive system and simultaneously lowering the maintenance costs.

The digital twin of a drive system is understood in the content of the present disclosure to mean a simulation model of the drive system, which for example may be present in the form of an FMU model (FMU=Functional Mock-up Unit)—for example as a .fmu file, which can be used to simulate at least one selected sub-aspect of the behavior of the drive system.

Such FMUs can be linked to one another via what are known as Functional Mock-up Interfaces, or FMIs for short (see https://fmi-standard.org/). FMI is a standard interface for exchanging model-based simulations between various simulation tools and environments. FMUs meet the FMI standard, but in principle can be connected via other interfaces or integrated into other environments.

FMI defines a standardized data format for model-based simulations, which is based on XML and binary files. It makes it possible to exchange model components and the connections thereof between various simulation environments and tools. It makes it possible to create complex systems consisting of various components and models, which can be embedded into various simulation environments and tools.

In particular, FMI supports dynamic (time-based) models, which are based on different mathematical descriptions, such as differential equations, finite-state machines, event-controlled systems and more. In the FMI, it is also possible for interfaces to be defined, which enable the exchange of data between the model components and the control thereof by way of the simulation environment.

To the greatest possible extent, designing with the aid of digital twins takes place on a singular basis nowadays. This means, for example, that the linking of various tools and the digital twins, or between the digital twins if multiple drive systems are to be designed, takes place manually. For example, the main input variable for the design can be a snapshot of a load behavior for a drive network (closed-loop control unit with the electric rotating machine). In this context, the user must assess various these various snapshots manually and separately in each case in the design tool, and ascertain the optimum design himself.

Even in the case of more complex installations, which can contain multiple drive networks, the user must assess the individual networks manually (for example for designing a supply in the case of a multi-axle unit or parallel connection of supplies and the interactions between the network-side filter modules.

The object underlying the present disclosure is therefore to provide methods and systems for designing drive systems, which are quicker and easier to handle compared to the design methods and systems which already exist, and in doing so deliver more accurate design results.

This object is achieved by a computer-assisted method mentioned in the introduction for designing at least one drive system, i.e. for specifying parameters of the real drive system, wherein
S1: a configurable digital twin of the drive system—a drive twin—and a predefined configurable model of the controlled system—a system model—are provided,
S2: the drive twin is linked with the system model to form an executable digital twin of the overall system—an overall twin, wherein parameterization takes place during the linking of the drive twin, whereby a starting parameter set of the drive twin is specified,
S3: the overall twin is executed, in order to simulate the behavior of the overall system and thereby to obtain simulation results,
S4: the drive system of the overall system is designed in accordance with the starting parameter set,
S5: the simulation results are compared with the behavior of the overall system,
S6: if the behavior of the overall system deviates from the simulation results, then at least the drive twin is optimized in terms of a predefined optimization target, by varying one or more parameters from the starting parameter set (110) that are interrelated with the predefined optimization target, in order to minimize the deviation of the behavior of the overall system (103) from the simulation results (113), whereby an optimized parameter set of the drive twin is obtained,
S7: the drive system of the overall system is designed in accordance with the optimized parameter set. This specifies/creates an optimized drive system for the controlled system.

An executable digital mapping of the drive system which describes its behavior, i.e. its digital twin, represents a simulation which is parameterized with the same parameters as the real system.

Thus, the term “parameter” can be a software and hardware characteristic.

In other words, anything that can be set in a model (drive twin, overall twin) is a parameter. In a real drive, a “parameter” can refer to a specific item of data of the closed-loop control software. Thus, the optimized parameter set can be present in the form of an (optimized) project planning file for the drive software and/or a proposal to use a more optimal motor, and accordingly can be used in the real drive system.

From the perspective of the simulation, both of these—project planning file for the drive software and description of the parameters of a more optimal motor—are parameters.

The drive system influences the controlled system directly. This also includes the cases in which the drive system acts as “interrupter” in the controlled system. In particular, this can be the case in the event of network feedback (line-bound EMC). These are to be assessed in accordance with various standards and guidelines (for example DIN 61000-4-7). In such a case, the method described here can be used in order to demonstrate conformity with such standards. In this context, the drive system, for example the converter, interferes with the network, wherein it should be demonstrated that certain interference levels are not exceeded, in order to accept the side effect of the influence of the drive system on the network.

The linking of the drive twin with the system model can take place in a design, simulation or engineering tool, for example.

After the linking, in principle it is possible for simulation of a controlled operation to take place (drive system controls the process), in which for example the drive system influences the temperature of an environment or is operated in voltage/frequency mode.

After the linking, the drive twin can exchange data with the system model and act as control loop, for example. This makes it possible to simulate a closed-loop operation.

In one embodiment, it can be provided that multiple drive systems are designed, wherein multiple drive twins can be linked with one another and/or with the system model. In this context, it can be provided that different drive systems are to control different processes, and in particular in a closed-loop manner, wherein the processes can influence each other.

In summary, the overall twin can comprise a plurality of drive twins and system models, which are linked with one another in a particular manner that is defined by the usage scenario.

A drive system is preferably embodied as an electronic closed-loop control unit, for example as a converter, in particular as a frequency converter.

In one embodiment it can be provided that the drive system additionally comprises an electric rotary machine, preferably on an electric motor, for example a synchronous motor (due to higher dynamics) or asynchronous motor.

In particular, it can be provided that the electronic closed-loop control unit is coupled to the electric rotary machine, in order to supply it with current and voltage with particular predefinable characteristics (amplitude, frequency, etc.). Such drive systems (electronic closed-loop control unit and electric rotary machine) are well known in the field of automation technology and are used, for example, to set mechanical facilities of an automation installation into motion. To this end, the drive systems can drive axes of a machine tool or a robot arm, pumps (hydraulic drive), conveyor belts, etc., for which reason they are often also referred to as “drives”.

In other words, drive trains are used in a wide range of contexts. A non-exhaustive list of the applications includes guiding movement; electromechanical drive systems in a machine tool; drive of the machine tool; DC motor use at the intermediate circuit; battery management; network-side applications for achieving the correct design of the network filters for example, and many more. The electronic closed-loop control unit, for example the converter, can then be controlled in a closed-loop or open-loop manner or can act as an interrupter in these processes. A corresponding optimum can be examined in each of these scenarios in a simulation using the digital twin, and an optimum closed-loop/open-loop control strategy or minimum interference impact etc. can be ascertained.

The starting point of the design (first rough design, first design stage), which leads to the ascertaining of the starting parameter set, can be an environment model (programmable logic controller (PLC), application (mechanics), supply network, other drives, DC rail/DC application, cooling medium . . . ) in a time-based simulation language (optionally integrated into the design tool), in order to enable a simulation program-based problem description. It is possible to leave open which parts are specifically in the environment model and which are in the object to be designed of the drive system. For example, the PLC can also be in the drive twin and can be stored in various levels of abstraction (for example as fuzzy logic).

In one embodiment, it can be provided that steps S3 to S7 are repeated at least once. In this context, the optimized parameter set is used on each repetition as initial or starting parameter set—next or second design stage. In particular, this makes it possible to use a mathematical optimization method for the design, if this is represented as an optimization problem of a multi-dimensional function.

In one embodiment, it can be provided that optimization takes place in terms of different optimization targets on different repetitions (in different design stages).

On each repetition, it can be expedient if the drive twin and preferably the simulation models are simulated with the same environment model, or one that is likewise more detailed, and is reviewed in terms of definable quality criteria. This can be necessary depending on the target criterion.

There can also be notes (during the iterative design process described here) to change the environment model, in order to achieve an improved quality in terms of optimization criteria of the overall twin (for example recommending to change the load profile or movement profile, or similar). For this purpose, it can be expedient to define which parameters of the surrounding model are subjected to tolerances.

In one embodiment, it can be provided that the drive twin is configurable in terms of its level of detail and/or the system model is configurable in terms of its level of detail, wherein immediately before or during the optimization, the level of detail of the drive twin and/or of the system model is changed, wherein preferably it is possible to set the number and/or type of the connection points and/or sample rates.

The level of detail of a model relates to the amount and accuracy of the information that is integrated into the model. A highly detailed model contains a large amount of information that is specific and detailed, while a minimally detailed model only contains basic information.

A model with a higher level of detail is generally more complex and more accurate, as it considers specific variables and factors to a greater extent. However, a higher level of detail can also lead to higher computing outlay and potentially make the model more difficult to understand and interpret.

In principle, the level of detail depends upon the application of the model and upon which information is relevant for the specific problem. In some cases, a minimally detailed model can be sufficient, while in other cases a higher level of detail is necessary in order to achieve more accurate results.

In the present case, it can thus be provided that the detail of the drive twin and/or the system model is adapted to each design stage. Optionally, this can mean going into more detail (if more details are required) or going into less detail for sub-aspects (if details are not currently important).

For example, it can be provided that the level of detail of the system model (before or during the optimization) is increased by supplying additional information (for example details on the mass distribution in the drive train, loss resistances in the lines, flow channels in the cooling, etc.). A refinement of the system model takes place here. The information demand and thus also the amount of additional information can be dependent upon the preceding design stage here.

In this context, it can be expedient if the drive twin is configurable in terms of its level of detail and the system model is configurable in terms of its level of detail and wherein, during the optimization, the level of detail of the drive twin is adapted to the level of detail of the system model, or vice versa.

In one embodiment, it can be provided that the drive twin comprises multiple simulation models, which can be parameterized, can be linked with one another, can be coordinated with one another or are compatible with one another.

It can also be provided that, in each simulation model, for example in the corresponding domains, the level of detail can be adapted.

In the present case, being able to be coordinated with one another or being compatible with one another means that, if these simulation models are linked with one another, particular values are pre-populated. In this context, the threshold values can change, or particular parameters can have other tolerance limits.

In one embodiment, it can be provided that different simulation models are assigned to different simulation domains.

In one embodiment, it can be provided that each simulation model is a stationary (time-independent) or dynamic (time-based) simulation model.

In one embodiment, it can be provided that the simulation model is a thermal simulation model, an electrical simulation model, a mechanical simulation model, a magnetic model, an acoustic model, an information technology-related model, for example an information electromagnetic or a closed-loop control-related model, or a combination thereof. In particular, the simulation model can be embodied as a combination of an information electromagnetic model and a closed-loop current control circuit.

The selection of the appropriate drive twin or the appropriate simulation models, for example during the rough design, can take place on the basis of the interfaces and the known information. This selection can take place on a knowledge base of existing designs with similar boundary conditions (with indication of the degree of filling) (for example by way of generative neural networks).

It can be provided that multiple variants of the drive twin are examined (in parallel, for example). In this context, various motor variants, converter sizes, software options, etc. can be examined, which meet the predefined boundary conditions that are predefined by the system model. The control of the variation can take place via known methods for global non-linear optimization with auxiliary conditions (for example, methods analogous to nature (evolutionary, swarm-based algorithms)). For example, by varying a starting design (various starting parameter sets) and using a genetic algorithm in multiple steps, it is possible to discover a new starting design (optimized starting parameter set), with which it is possible to enter the next level of detail (design stage). In other words, this design can take place up to an abort criterion (for example drive selection no longer changes), in order to cover various scenarios of the surrounding system. The ascertained optimized starting parameter set can then be transferred into the drive twin, whereby a drive twin of a higher level of detail is generated. It is also possible for multiple of these higher-level-of-detail DTs to exist, these existing in parallel (for example, different simulation domains) or building upon one another in series (for example, Increasingly high levels of detail).

In one embodiment, it can be provided that the controlled system additionally has at least one feedback.

Open-loop control is closed-loop control without feedback. Feedback in closed-loop control technology relates to the process in which part of the output signal of a system is fed back, in order to modify the input signal and thus to regulate the behavior of the system. Specifically, this means that the output signal of the system (for example, the speed of a motor) is compared with a target value that is specified by the user or by the system itself. If there is a deviation between the output signal and the target value, then an error is identified, and a correction signal is generated and applied to the input signal of the system. The result is a closed-loop control circuit, which adapts the behavior of the system on a continuous basis, in order to reach and maintain the target value.

In one embodiment, it can be provided that the simulation results comprise information regarding an interaction behavior of the drive twin with the system model.

In other words, the simulation of the overall twin generates information regarding the interaction behavior of the drive twin with the environment model (system model) as the result. This information can be, for example, a load profile of the drive, the effect of different multi-axle modes on one or parallel supplies and the surrounding system.

This information or the interaction behavior can be used as the basis for the subsequent design steps.

It can be provided that the design process, for example at each design stage, gives feedback as to the extent to which the drive twin can still be refined.

The aforementioned simulation (of the overall twin or parts thereof) can take place on external resources, for example on a cloud platform. Advantageously, variants can be calculated in parallel here, without scaling up the time investment.

In summary, the disclosed method makes use of different stages of detail of drive twins, in order to offer a solution for a predefined problem in terms of predefinable optimization criteria. The design process can additionally be integrated into an iterative detailing of the model through the formation of variants.

The invention is explained in greater detail below on the basis of exemplary embodiments, where:

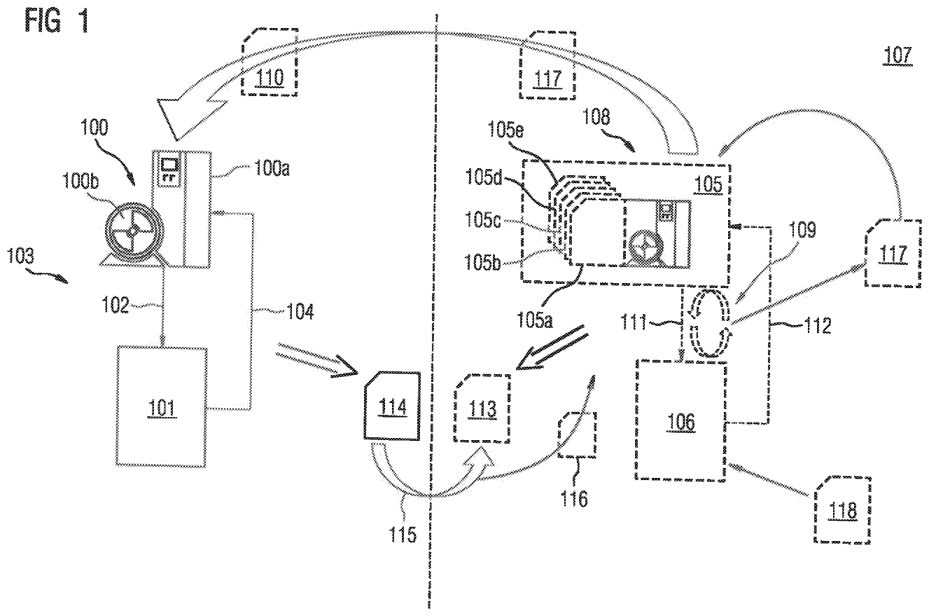

FIG. 1 shows a system for designing a drive system,

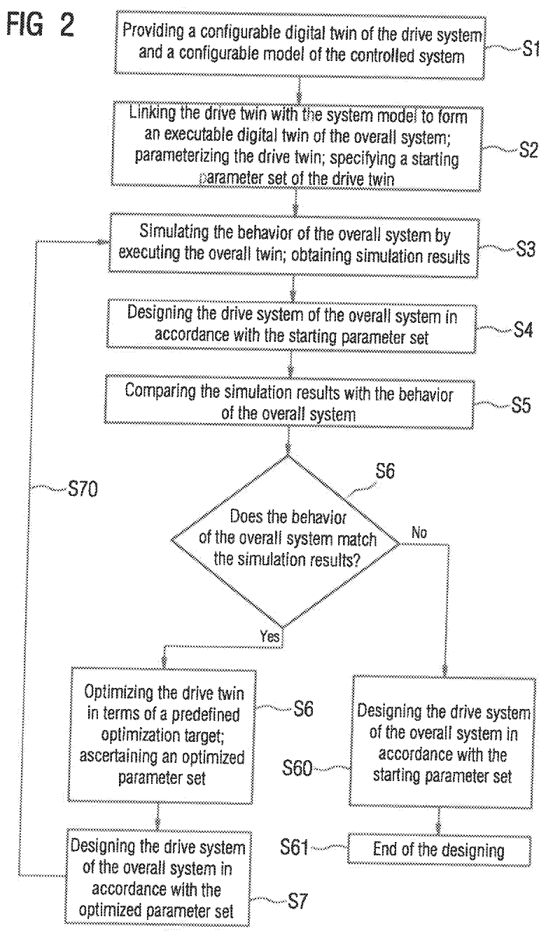

FIG. 2 shows a flow diagram of a method for designing a drive system, and

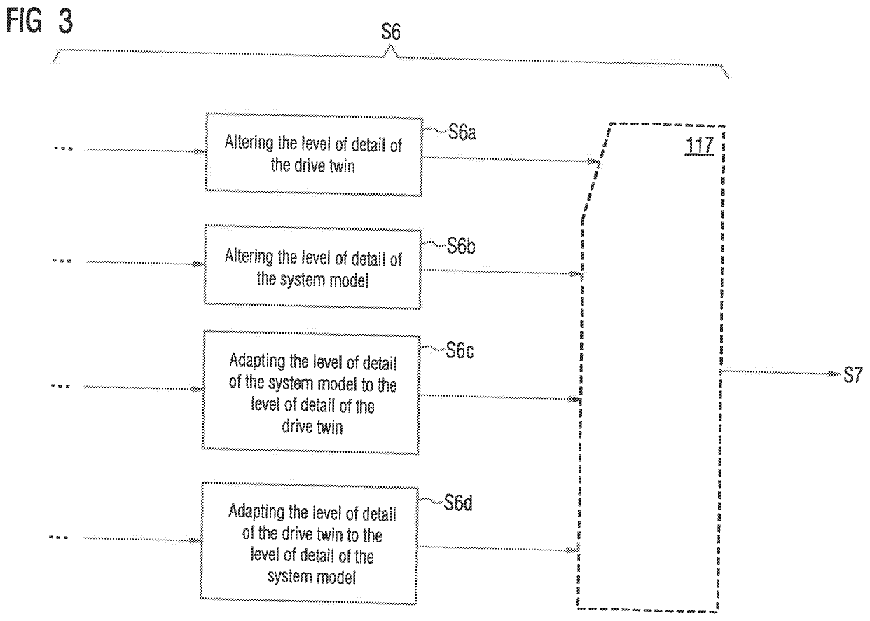

FIG. 3 shows possible embodiments of the optimization step in FIG. 2.

The reference characters used in the figures are used exclusively to improve readability and are not to be construed as limiting. The same reference characters in different figures refer to substantially identical elements or subject matter.

FIG. 1 shows a (not yet designed) drive system 100, which is to become part of an automation system (not shown here) (after being designed). The drive system 100 can be embodied as an electronic closed-loop control unit 100a, for example as a converter, in particular as a frequency converter.

The drive system 100 can additionally comprise an electric rotary machine 100b, preferably an electric motor, for example an asynchronous motor.

In this context, the electronic closed-loop control unit can be coupled to the electric rotary machine, in order to supply it with current and voltage with particular predefinable characteristics (amplitude, frequency, etc.) and, as a result, for example, to reduce or increase its torque to the required level, in order to meet the requirements for the use.

Such drive systems can, for example, drive axes of a machine tool or a robot arm, pumps (hydraulic drive), conveyor belts, etc., for which reason they are often also referred to as “drives” or “drive trains”.

The drive system 100 directly influences a (real) predefined process 101. In closed-loop control technology, a process is often used as a synonym for the term controlled system.

In this context, for example, the application can be supporting commissioning, supporting diagnostics, supporting training measures, etc.

The direct effect of the drive system 100 on the process 101 is illustrated by an arrow 102.

Together, the drive system 100 and the process 101 form an overall system 103.

Additionally or optionally, the process 101 can have a feedback 104. An open-loop control (controlled system) with a feedback is referred to as closed-loop control (closed-loop controlled system or control loop).

Digital twins can be used in order to obtain knowledge regarding the requirements placed on the drive system 100 by the process 101, even before commissioning the automation system for example.

In the present case, a digital twin of the drive system 100—a drive twin 105—and a model of the controlled system 101—the system model 106—are provided. These are preferably designed as software modules that are separate from one another, for example, and can be linked with one another, for example via an FMI (Functional Mock-up Interface).

A linking can be carried out for example in a configuration/parameterization tool or a design tool or an engineering tool 107 of an engineering platform. The linking generates a digital twin of the overall system 103—the overall twin 108.

In this context, the linking is not a pure applicative connection, but rather enables a data exchange 109 between the models, i.e. between the drive twin 105 and the system model 106.

The selection of the drive twin 105 can take place for example on the basis of the interfaces and the known information relating to the present application case. This selection can take place on a knowledge base of existing designs with similar boundary conditions (with indication of the degree of filling), for example using generative neural networks.

The aim of the designing is to find a drive system 100 appropriate for the process 101.

The system model 106 is predefined by the application or by the process 101. In this context, the system model 106 can describe one or more of the following applications: PLC, application (for example, mechanics), supply network, other drives, DC rail, cooling medium, and many more.

Preferably, the system model 106 is available in a time-based simulation language (optionally integrated in the design tool 107), in order to enable a simulation program-based problem description.

Both the working twin 105 and the system model 106 can be configured.

The drive twin 105 can comprise multiple simulation models 105a, 105b, 105c, 105d, 105e which can be parameterized, linked with one another and coordinated with one another, wherein different simulation models 105a to 105e are preferably assigned to different simulation domains. The drive twin 105 can thus comprise one or more of the following models 105a to 105e, for example: thermal simulation model, electrical simulation model, mechanical simulation model, information technology-related model (for simulating closed-loop control, logic, data pre/post-processing, . . . ), a magnetic model, an acoustic model. In particular, the simulation model can be embodied as a combination of the information electromagnetic model and a closed-loop current control circuit.

In this context, “able to be coordinated with one another” primarily means that, if various simulation models are linked with one another, particular values of the parameters of the simulation models 105a to 105e are coordinated with one another and are prepopulated accordingly. Compared to the non-linked simulation models 105a to 105e, this can mean for example that particular parameters have other threshold values and/or tolerance limits.

Each simulation model 105a to 105e can be designed as a static (time-independent) simulation or as a dynamic simulation model, which enables a time-based simulation. In this context, for example, it can be made possible to observe closed-loop rotational speed control behavior or network harmonics.

The selection of the appropriate simulation models 105a to 105e can take place, as in the selection of the drive twin 105 described above, on the basis of the interfaces and the known information regarding the process 101 or regarding the system model 106. This selection can take place on a knowledge base of existing designs with identical or similar boundary conditions (preferably with indication of the degree of filling), for example with the aid of generative neural networks.

Moreover, the drive twin 105 can be configurable in terms of its level of detail. This means, for example, that each simulation model 105a to 105e comprised by the drive twin 105 can be configured in terms of its detail. In this context, for example, it can be possible to set the number and/or the type of the connection points and/or the sample rates.

Additionally, the system model 106 can also be configurable in terms of its level of detail.

In other words, the drive twin 105 and/or the system model 106 can be embodied in such a manner that it is possible to make them more or less detailed at any time.

In particular, the level of detail of the drive twin 105 can be adapted to the level of detail of the system model 106, or vice versa.

In summary, the drive twin 105 is first parameterized during linking. In doing so, one or more simulation models 105a to 105e appropriate for the system model 106 can be chosen in the drive twin 105. This specifies a starting parameter set 110 of the drive twin 105. The starting parameter set 110 can be used directly to design the drive system 100. In other words, a first “rough designing” of the drive 100 can take place with the first linking.

A possible initial parameterization can result, for example, from automatic closed-loop controller settings (and possibly with targeted additional inputs) (for example one-button timing).

In other words, the focus in the first rough design step should be on the realization of the desired function of the usage scenario, but not on the restrictions of the potential solution portfolio.

In this context, the drive twin 105 can select one or more low-level-of-detail models 105a to 105e (generic digital twins) and parameterize them to any extent that is known from the drive system 100.

With the (now parameterized) overall twin 108, it is possible to simulate the overall system 103. A simulation is performed, in which the influence 102 of the drive system 100 on the process 101 and preferably also the feedback 104 are simulated (arrows 111, 112), and simulation results 113 are thereby obtained. In this context, one or more closed control loops 112 are simulated. The simulation results 113 can be present, for example, in the form of a load curve or multiple load curves for actual load over time.

In this context, made possible by the ability to choose and/or configure the drive twin 105 and its simulation models 105a to 105e, it is possible to examine multiple variants (for example in parallel). To this end, for example, motor variants, converter sizes, (company) software options can be varied, these meeting the predefined boundary conditions that are established in the predefined process 101 or system model 106. The control of the variation can take place via known methods for global non-linear optimization with auxiliary conditions (for example, methods analogous to nature (evolutionary, swarm-based algorithms)). For example, by varying the starting or rough design and using a genetic algorithm in multiple steps, it is possible to discover a new starting design, with which it is possible to enter the next level of detail.

The simulation of the drive twin 105 (or parts thereof 105a to 105e) or also of the overall twin 108 can take place internally, Le. within the automation installation, or on external resources, for example using a cloud infrastructure. Advantageously, variants can be calculated in parallel here, without scaling up the time investment.

The simulation results 113 can comprise information regarding the interaction behavior of the drive twin 105 with the system model 106. These can include at least one of: load profile of the drive; the effect of different multi-axle modes on one or parallel supplies and the surrounding system, etc.

This interaction behavior can form the basis for the subsequent design steps (see below).

Alternatively or additionally, the interaction behavior can be used in order to examine an effect of the changing of the system model 106 on the drive twin 105, i.e. on the parameterization thereof.

In other words, a low-level simulation (rough design) of the overall twin 108 can be initiated and executed up to a particular abort criterion, for example until the drive selection (the parameterization of the drive twin 105) does not change any further. This covers various scenarios of the surrounding system 106. It is not necessary here to limit just to a worst-case scenario that in turn is dependent upon empirical values, but rather to keep the solution space deliberately open. The parameterization achieved thereby can be used as starting parameter set 110, in order to reparameterize the drive twin 105, for example.

Subsequently to or in parallel with the simulation, the behavior of the overall system 103 is also examined, wherein the drive system 100 of the overall system 103 has been designed in accordance with the starting parameter set 110. In this context, real (experimental) data 114 is gathered regarding the behavior of the overall system 103.

The simulation results 113 are compared 115 with the data 114 that characterizes the behavior of the overall system 103.

As a rule, the behavior of the overall system 103 during the first rough design deviates from the behavior of the overall twin 108, meaning that the simulation results 113 do not match the measurement values 114.

A calibration of the overall twin 108 to the real measurement values 114 can take place at this point, in order to ensure the necessary error reconciliation.

In a first step, for example, it is achieved that the overall twin 108 behaves sufficiently consistently with the overall system 103, i.e. that the simulation results 113 from the simulation of the overall twin 108 lie within defined limits and/or meet criteria, for example. This can be achieved by means of a mathematical optimization method, in which one or more parameters from the starting parameter set 110 are varied. It is understood that the varying of the parameters from the starting parameter set 110 influences the simulation results. During optimization, in this context there is a search for any changed, optimized parameters, for which the deviation of the simulation results 113 from the behavior of the overall system 103 is lowest or the simulation results lie within defined limits and/or meet particular criteria, for example. To this end, a conventional optimization method can be used: Ansys optiSLang; Optimization Toolbox from MATLAB or Simcenter HEEDS.

Normally, the uncertainty of the model grows from closed-loop drive controller up to the system model. In other words, if the software parameters and controller topology are identical, then the configuration and component data of the drive system 100 are known (but can include tolerances or be from a third-party manufacturer), but by contrast the open-loop or closed-loop controlled system 101 has the most uncertainties. This means that the main focus of the system to be calibrated lies on the parts of the system that are “furthest away” from the drive system 100.

However, the deviation can yield knowledge regarding the aspects of the overall twin 108 and in particular of the drive twin 103 that need optimizing.

The drive twin 105 can thus be optimized in terms of a predefined optimization target 116, by varying any parameters from the starting parameter set 110 of the drive twin 105 that are interrelated with the optimization target 116, and subsequently examining the effect of the variation of the parameters on the simulation results 113 obtained from the simulation of the overall twin 108. In this context, it is possible to search for an optimum, preferably for a minimum, under the condition that the simulation results 113 from the simulation of the overall twin 108 lie within defined limits and/or meet particular criteria. This yields an optimized parameter set 117 of the drive twin 105, which can be used for designing the drive system 100. The output (of the converter) and the costs, for example, are one of many examples of the interrelationships between parameters and optimization targets.

The optimization can take place in terms of various optimization criteria or weighted individual criteria, such as:
costs,
closed-loop control accuracy,
closed-loop control quality,
performance, particularly in the sense of throughput, set duration of a closed-loop controlled variable,
energy consumption,
consequences for the peripherals (available interfaces for auxiliary variables (for example cooling or voltage levels)),
space requirement, in particular cumulative space requirement,
year of release,
prospective service life,
prospective maintenance intensity,
EMC class,
other standard classes,
etc.

These criteria can also be combined and populated with (different) weightings.

A detailed BOM (Bill of Materials) or the pre-commissioning project for the transfer into the real drive system 100 are examples of results.

Immediately before or during the optimization, the level of detail of the drive twin 105 and/or the of the system model 106 can be changed.

For example, the level of detail of the drive twin 105 or also of the simulation models 105a to 105e can be chosen automatically on the basis of the environment model 106.

In particular, it is possible to go into more detail (if more details are required) or go into less detail (if particular details are not currently important) for the drive twin 105 and/or the system model 106. In this context, an optimization of particular constituent parts of the drive twin 105, for example of the converter model and/or of the model of the electrical rotating machine and the operation thereof can take place, in order to better adapt the drive twin 105 to the system model 106.

Additionally, it can be expedient to supplement the system model 106 (before or during the optimization) with additional information 118 (for example details on the mass distribution in the drive train, loss resistances in the lines, flow channels in the cooling, etc.), or to refine it with the additional information 118. A calibrated model, for example with the aid of field data, or a model of component suppliers, is additionally considered as additional information here for example.

The optimized parameter set 117 is subsequently used for designing the drive system 100. This yields an optimized or optimally designed drive system 100 for the controlled system 101,

The optimized parameter set 117 (a copy thereof) can also be stored for later use during operation. In this context, the optimized parameter set 117 can be transferred into the drive twin 105 or into another digital twin, in order to use said digital twin later, for example during operation.

In other words, a drive system 100 in is now present in a next design stage. If the optimized parameters 117 are transferred into the drive twin 105 or into another digital twin, a higher-level-of-detail digital twin is obtained, which possibly can parameterize the drive system 100 as part of an (automated) commissioning. It is also possible to achieve multiple of these higher-level-of-detail digital twins, which can be able to be used simultaneously/in parallel (for example, as different simulation domains) or can build upon one another in series (for example, increasingly high levels of detail).

The aforementioned steps—simulating, testing, optimizing, transferring results of the optimization to the drive system 100—can be repeated as often as desired (see S70 in FIG. 2). In this context, the optimized parameter set from the preceding design stage is used as initial parameter set.

Additionally, the optimization target can be re-specified on each repetition. Moreover, the level of detail of the drive twin 105 and/or of the system model 106 can be altered or adapted. Thus, optimization can take place in terms of different optimization targets on different repetitions. In this context, the information requirement for the drive twin 105 and/or for the system model 106 can depend upon the preceding design stage.

On each repetition, it can be expedient if the drive twin 105 and preferably the simulation models 105a to 105e are simulated with the same environment model 106, or one that is likewise more detailed, and is reviewed in terms of definable quality criteria. This can be necessary depending on the target criterion.

On the basis of the results from the repetition, the design cycle can be iteratively further refined, until a corresponding abort criterion is available.

As a result of the simulation with the overall twin 108, there can also be notes to change the environment model 106, in order to achieve an improved quality in terms of the optimization criteria of the overall twin 108 (for example recommending to change the load profile, the characteristics of the movement profile, or similar). For this purpose, it can be expedient to define which parameters of the surrounding model are subjected to tolerances (probabilistic design/Sören's stochastic approach).

With the iterative approach for assessing alternative variants of a system, a sensitivity analysis can also take place, with the result of which it is also possible to carry out trade-off evaluations on the requirement side. This makes it possible to define an improved offer in the portfolio. For example, “If the tolerance for the value “x” can be reduced, then the energy consumption falls by “y”—is this an option in the portfolio?”

FIG. 2 shows a flow diagram of a design method for a drive system, for example for the drive system 100. To this extent, FIG. 2 can be considered a summary of the steps already described in conjunction with FIG. 1,

In a step S1, a configurable digital twin of the drive system 100—the drive twin 105—and a configurable model of the controlled system 101—the system model 106—are provided.

In a step S2, the linking of the drive twin 105 with the system model 106 to form an executable digital twin of the overall system 103—the overall twin 108—takes place. In this context, “linking” means that the twins can exchange data. The drive twin 105 is parameterized during linking. After the parameterization, a starting parameter set 110 of the drive twin 105 is present, which can function as a first rough design of the drive system 100.

In a step S3, the behavior of the overall system 103 is simulated, by the overall twin 108 being executed. This generates simulation results 113.

The subsequent steps describe a verification of the simulation results, which can be performed iteratively until the desired result is achieved. In this context, multiple design stages (iterations) can be necessary, in order to reach the desired result. “The desired result” is mostly implemented as a predefinable abort criterion. If the criterion is met during a design stage, then the simulation results present at this stage are considered to be verified. The corresponding parameter set can be used for designing the drive system 100.

This means that in a step S4, the drive system 100 of the overall system 103 is first designed in accordance with the starting parameter set 110—the rough design takes place.

In a step S5, the simulation results 113 are compared with the behavior of the overall system 103.

In a step S6, it is first checked whether behavior of the overall system 103 deviates from the simulation results 113, which generally often might well be the case in the first rough design.

However, if no deviation is established, then the starting parameter set 110 is already considered to be verified and can be used for designing the drive system 100—step S60. In this case, the design ends after adoption of the starting parameter set 110—step S61.

If a deviation is established, then it can be analyzed, in order to establish where there is an optimization requirement. In this context, for example, it can be examined whether there is a particular domain (electrical, thermal, mechanical), in which the simulation does not match the experimental data 114 or whether there are other chosen parameters of the drive 100, which contribute to non-optimum control of the process 101.

In any case, the drive twin 105 is optimized in terms of an optimization target, wherein the optimization target can be ascertained and specified on the basis of the analysis of the deviation that has taken place.

In this context, it can be expedient to alter the level of detail of the drive twin 105 and/or of the system model 106, in order to obtain better optimization results.

The following sub-steps are possible, for example (see FIG. 3). In step S6a, for example, only the level of detail of the drive twin 105 is changed, without the level of detail of the system model 106 being changed in this context. In step S6b, for example, conversely only the level of detail of the system model 106 is changed, without the level of detail of the drive twin 105 being changed in this context. It is also conceivable that the level of detail both of the drive twin 105 and also of the system model 106 is changed.

The changing can be making the aspects of the of the corresponding models more detailed or also less detailed.

For example, number and/or type of the connection points and/or sample rates of the models can be changed.

Moreover, the changing of a model, for example of the drive twin 105, can also make it expedient to adapt the system model 106. In this case, the level of detail of the system model 106 is adapted to the level of detail of the drive twin 105—step S6c.

The inverse case is likewise conceivable, in which—as in step S6d—the level of detail of the drive twin 105 is adapted to the level of detail of the system model 106.

As part of this optimization S6, preferably S6a, S6b, S6c or S6d, an optimized parameter set 117 is generated for the drive twin 105 (see FIG. 3), with which the drive system 100 can be designed.

In a step S7, the drive system 100 of the overall system 103 is designed in accordance with the optimized parameter set 117. This creates an optimized drive system 100 for the controlled system 101, The optimized parameter set 117 can now also be verified. To this end, the aforementioned steps from step S3 can be repeated—S70, wherein to simulate the drive twin 105 parameterization takes place with the optimized parameter set 117 and not with the starting parameter set 110.

The configuration and parameterization tool 107 can be stored in a computing facility (not shown here) and executed from there. The computing facility, for example, can be embodied as a system of computers communicating with one another, for example as a cloud infrastructure.

The computing facility comprises an engineering platform. The engineering platform can comprise configuration and parameterization tools 107 and execute them. In this case, the engineering platform comprises a corresponding solver, in order to execute the aforementioned models.

The aforementioned models and in particular the overall twin 108, however, can also be executed as a co-simulation in the computing facility. This means that the models are not executed by the engineering platform and are not embodied as part of the engineering platform. In this case, an inter-process communication takes place between the engineering platform and, for example, the overall twin 108 or a part of the overall twin 108, for example the drive twin 105 or system model 106. In this inter-process communication, the engineering platform executes a sub-process, which supplies the one or more of the aforementioned models (for example the overall twin 108, the drive twin 105, the system model 106, etc.) with corresponding information necessary for the simulation, and preferably orchestrates the simulation. In this context, the engineering platform does not contain any solver that is responsible for the execution of the corresponding model/models. In particular, the solver can run on a remote computer, for example in the cloud.

The object of this description consists merely in providing illustrative examples and indicating further advantages and particular features of this invention. Thus, it cannot be interpreted as a limitation of the field of application of the invention or of the patent rights claimed in the claims. In particular, the features disclosed in conjunction with the methods described here can be used in a meaningful manner to develop the systems described here, and vice versa.

1-15. (canceled)

16. A computer-assisted method for designing at least one drive system which directly influences a controlled system, wherein the drive system and the controlled system together form an overall system, the method comprising:
(S1) providing a configurable digital twin of the drive system, a drive twin, and a predefined configurable model of the controlled system, a system model;
(S2) linking the drive twin with the system model to form an executable digital twin of the overall system, an overall twin, wherein parameterization takes place during the linking of the drive twin, whereby a starting parameter set of the drive twin is specified;
(S3) running the overall twin in order to simulate a behavior of the overall system and thereby to obtain simulation results;
(S4) designing the drive system of the overall system in accordance with the starting parameter set;
(S5) comparing the simulation results with the behavior of the overall system;
(S6) optimizing at least the drive twin, when the behavior of the overall system deviates from the simulation results, in terms of a predefined optimization target, by varying one or more parameters from the starting parameter set that are interrelated with a predefined optimization target, in order to minimize a deviation of the behavior of the overall system from the simulation results, whereby an optimized parameter set of the drive twin is obtained; and
(S7) designing the drive system of the overall system in accordance with the optimized parameter set.

17. The method of claim 16, wherein steps S3 to S7 are repeated at least once.

18. The method of claim 17, wherein the optimizing takes place in terms of different optimization targets on different repetitions.

19. The method of claim 16, wherein the drive twin is configurable in terms of its level of detail and/or the system model is configurable in terms of its level of detail, wherein the level of detail of the drive twin and/or the system model is changed during the optimizing.

20. The method of claim 19, wherein number and/or type of connection points and/or sample rates of the drive twin and/or of the system model are changed.

21. The method according of claim 19, wherein the drive twin is configurable in terms of its level of detail and the system model is configurable in terms of its level of detail and wherein, during the optimizing, the level of detail of the drive twin is adapted to the level of detail of the system model, or vice versa.

22. The method of claim 16, wherein the drive twin comprises multiple simulation models which are parameterized, linked with one another, and coordinated with one another.

23. The method of claim 22, wherein different simulation models are assigned to different simulation domains.

24. The method of claim 22, wherein each simulation model is a stationary or dynamic simulation model.

25. The method of claim 24, wherein each simulation model is a thermal simulation model, an electrical simulation model, a mechanical simulation model, a magnetic model, an acoustic model, an information technology-related model, for example an information electromagnetic or a closed-loop control-related model or a combination thereof, or a combination thereof.

26. The method of claim 16, wherein the controlled system additionally has at least one feedback.

27. The method of the claim 16, wherein the simulation results comprise information regarding interaction behavior of the drive twin with the system model.

28. A computing facility comprising an engineering platform, which is configured to carry out or orchestrate the method of claim 16.

29. A non-transient machine-readable storage medium storing a computer program comprising instructions which, when executed by a computing facility comprising an engineering platform, cause the computing facility to carry out the method of claim 16.
